(19) United States
(12) Patent Application Publication
(10) Pub. No.: US 2008/0105820 A1
(43) Pub. Date: May 8, 2008

(54) RESONANT STRUCTURES FOR ELECTROMAGNETIC ENERGY DETECTION SYSTEM AND ASSOCIATED METHODS

(76) Inventor: Robert H. Cormack, Boulder, CO (US)

Correspondence Address: LATHROP & GAGE LC, 4845 PEARL EAST CIRCLE, SUITE 300, BOULDER, CO, 80301, US

(21) Appl. No.: 11/936,349

(22) Filed: Nov. 7, 2007

Related U.S. Application Data
(60) Provisional application No. 60/864,647, filed on Nov. 7, 2006.

(51) Int. Cl. H01L 31/0232

(52) U.S. Cl. 250/216; 257/184; 257/187; 257/432

(57) ABSTRACT

An electromagnetic energy detection system, for detecting electromagnetic energy incident thereon, includes a resonant structure which includes first and second reflective regions separated by a photosensitive region such that electromagnetic energy entering the resonant structure is multiply reflected therein for detection by the photosensitive region.

### RELATED APPLICATIONS

This application claims priority to U.S. Provisional Application No. 60/864,647, entitled “Resonant Detectors,” filed on 7 Nov. 2006 and incorporated herein by reference.

### BACKGROUND

Photosensitive detectors, such as photodiodes (including thin film photodiodes) and phototransistors (including thin film phototransistors), are limited in their detection efficiency due to the mechanical limitations imposed by the detector pixel geometry or by the collection efficiency of the photosensitive material used. Many current CMOS detector pixels include photosensitive regions that are constructed using crystalline semiconductors such as silicon. These crystalline semiconductor materials have good collection efficiencies, but are subject to the following limitations: a) the photosensitive region must share space on the crystalline wafer with pixel circuitry, making the photosensitive region smaller than the pixel area; and b) the opaque conductive traces that connect the pixels to read-out circuits and other circuitry are placed in layers deposited over parts of the photosensitive region of the detector pixel. These limitations cause some of the electromagnetic energy incident on the detector to be blocked from reaching the photosensitive regions. This decrease in the collection efficiency may be partially corrected by the addition of lenslets at the expense of added manufacturing complexity. An alternative configuration for CMOS detector pixels uses a “top-hat” design (discussed below) instead of using a lenslet, locating the photosensitive region “above” the opaque traces (utilizing terminology recognized in the art, wherein “above” means further away from a common substrate and “below” means closer to the substrate). However, in the top-hat design the photosensitive regions are often fabricated from amorphous semiconductors (e.g., amorphous silicon) that exhibit lower collection efficiencies than crystalline semiconductors. Both the lenslet design and the top-hat design exhibit collection efficiencies less than 100 percent.

FIG. 1 shows a simplified, partial cross-section of a prior art detector pixel array 100. Detector pixel array 100 includes a plurality of detector pixels 105 (enclosed by a dotted outline) that are fabricated upon a substrate 110. Substrate 110 may be formed from, for example, semiconductor materials such as silicon. Each one of the plurality of detector pixels 105 includes a photosensitive region 120 and detector pixel read circuits 130. Detector pixel read circuits 130 may be shared between detector pixels 105. Photosensitive regions 120 and detector pixel read circuits 130 may be built into or onto substrate 110 using, for example, CMOS fabrication methods that are well known in the art. Detector pixels 105 also may share conductive traces 140 (e.g., made of metal) formed within an interconnection layer 145 above substrate 110. Interconnection layer 145 may be formed of a conventional material used in semiconductor manufacturing such as, but not limited to, silicon dioxide. Conductive traces 140 provide electrical connections from detector pixel read circuits 130 and photosensitive regions 120 to an overall system (not shown) containing detector pixel array 100. As shown in the example of FIG. 1, conductive traces 140 are formed above and between photosensitive regions 120. Thus, electromagnetic energy must travel past a network of conductive traces 140 in order to be detected at each photosensitive region 120. FIG. 1 shows only those conductive traces 140 that may limit the optical sensitivity; other traces that are not relevant to optical sensitivity are not shown.

As smaller devices are developed, detector pixel arrays with smaller detector pixel dimensions become advantageous. However, as detector pixel dimensions are made smaller, a fractional area (i.e., “fill factor”) occupied by a photosensitive region relative to the area of a corresponding detector pixel gets correspondingly smaller, since there is a minimum size that conductive traces 140 may be made without compromising the ability to read the signals generated within detector pixel 105. A reduced fill factor may further decrease the detection efficiency of detector pixels with smaller pixel dimensions.

To increase the electromagnetic energy detectable at photosensitive regions 120, a lenslet 150 may be formed over each detector pixel 105 to help concentrate and guide electromagnetic energy through the detector pixel structure and toward each photosensitive region 120. Normally-incident electromagnetic energy (indicated by dash-dot lines and enclosed by a bracket 160) is focused by lenslet 150 toward photosensitive region 120, where it is detected. However, off-normal electromagnetic energy (indicated by dash-dot lines and enclosed by a bracket 170) that is at a high incidence angle may be focused at a location other than photosensitive region 120, and thereby not detected. Furthermore, conductive traces 140, which may be opaque to specific electromagnetic wavelengths of interest, may block or scatter electromagnetic energy that falls thereon. Therefore, positioning of photosensitive regions 120 at the bottom of detector pixels 105 tends to limit photodetection efficiency of standard CMOS detector pixels of the design shown in FIG. 1.

FIG. 2 (prior art) shows an improvement over the prior art of FIG. 1. The detector pixel design shown in FIG. 2 is often described as a top-hat design and is more fully described in, for example, U.S. Pat. No. 6,501,065 to Uppal et al. and U.S. Pat. No. 6,995,411 to Yaung et al. A detector pixel array 200 includes a plurality of detector pixels 205 (enclosed by a dotted outline) fabricated upon a substrate 210 (e.g., a silicon wafer). Each one of the plurality of detector pixels 205 may include a detector pixel read circuit 220, conductive traces 230, a conductive layer 240 and a photosensitive region 250. Conductive traces 230 are shared between detector pixels. Using CMOS fabrication methods well known in the art, detector pixel read circuits 220 may be built into or onto substrate 210. During further fabrication, conductive traces 230 are created within an interconnection layer 245 above substrate 210. Conductive traces 230 provide electrical connections between detector pixel read circuits 220 and photosensitive regions 250 and additionally supply electrical connections to an overall system (not shown). In this top-hat design, photosensitive regions 250 are fabricated on top of conductive layers 240, which are themselves disposed above conductive traces 230. Since conductive traces 230 are disposed below photosensitive regions 250, normally incident electromagnetic energy (indicated by an arrow 260) as well as high incidence angle electromagnetic energy (indicated by another arrow 270) are both detectable by photosensitive regions 250.

The top-hat design, as illustrated in FIG. 2 may increase fill factor and remove certain ray angle and lens speed constraints of other CMOS detector pixel designs (e.g., as shown in FIG. 1) by forming photosensitive region 250 as a thin film stack by means of, for instance, vacuum deposition above conductive layer 240. Thin film photosensitive region 250 may be formed by deposition of silicon (or other semiconductors, such as gallium arsenide, germanium, and organic semiconductors), and may be an amorphous (i.e., not crystalline) material. Amorphous photosensitive regions often have defects where electron-hole pairs created by photons recombine before being collected into an external circuit and detected. Additionally, when such photosensitive regions are subjected to a reverse voltage bias—as is commonly done to increase collection speed and efficiency—such defects can be sources of electron-hole pairs which cause “dark current” (i.e., not caused by incident light) in the pixel. Therefore, such defects make such amorphous photosensitive regions 250 inefficient. Making amorphous photosensitive regions very thin (e.g., ˜100 nm) may reduce the number of defects in the photosensitive region available for carrier recombination and/or carrier sourcing and may lower the dark current; however, the photosensitive region may then be so thin that it absorbs only a few percent of the incident electromagnetic energy, thus producing little net increase in efficiency.

Alternatively, crystalline semiconductor photosensitive regions may be integrated into the top-hat design by using, for example, high precision wafer bonding. However, these fabrication processes may be disadvantageous because they are generally complex and expensive. Moreover, the collection efficiency of the resultant crystalline photosensitive regions would require further optimization. Additionally, for both amorphous and crystalline photosensitive regions in the top-hat design, incident electromagnetic energy (indicated by another arrow 280) may be partially absorbed by photosensitive regions 250 while a portion of incident electromagnetic energy 280 may be lost as reflected electromagnetic energy (indicated by another arrow 290); that is, reflected electromagnetic energy 290 is directed away from photosensitive region 250 and not available for detection. Furthermore, incident electromagnetic energy 280 may be further reflected and/or absorbed by conductive layer 240, thereby further reducing the detection efficiency of this top-hat design.

### SUMMARY

In one embodiment, an electromagnetic energy detection system for detecting electromagnetic energy incident thereon is disclosed. The electromagnetic energy detection system includes a resonant structure which includes first and second reflective regions separated by a photosensitive region such that electromagnetic energy entering the resonant structure is multiply reflected therein for detection by the photosensitive region.

In another embodiment, a method for electromagnetic energy detection using a photosensitive region is disclosed. The method includes configuring the photosensitive region with a thickness such that the photosensitive region detects a portion of electromagnetic energy incident thereon while transmitting, without detection, a remainder of the electromagnetic energy therethrough. The method also includes reflecting a portion of the remainder of the electromagnetic energy back into the photosensitive region for detection by the photosensitive region. In one embodiment, the photosensitive region is configured to have a thickness less than 100 nm.

In another embodiment, a resonant structure for electromagnetic energy detection is provided. First and second reflective regions are separated by a photosensitive region. Electromagnetic energy entering the resonant structure is multiply reflected therein for detection by the photosensitive region.

In one embodiment, a detector array has an array of resonant structures. Each of the resonant structures has first and second reflective regions separated by a photosensitive region. Electromagnetic energy entering the resonant structure is multiply reflected therein for detection by the photosensitive region.

### BRIEF DESCRIPTION OF THE DRAWINGS

The present disclosure may be understood by reference to the following detailed description taken in conjunction with the drawings briefly described below. It is noted that, for purposes of illustrative clarity, certain elements in the drawings may not be drawn to scale.

FIG. 1 is a cross-sectional illustration of a portion of a prior art detector pixel array incorporating a lenslet array.

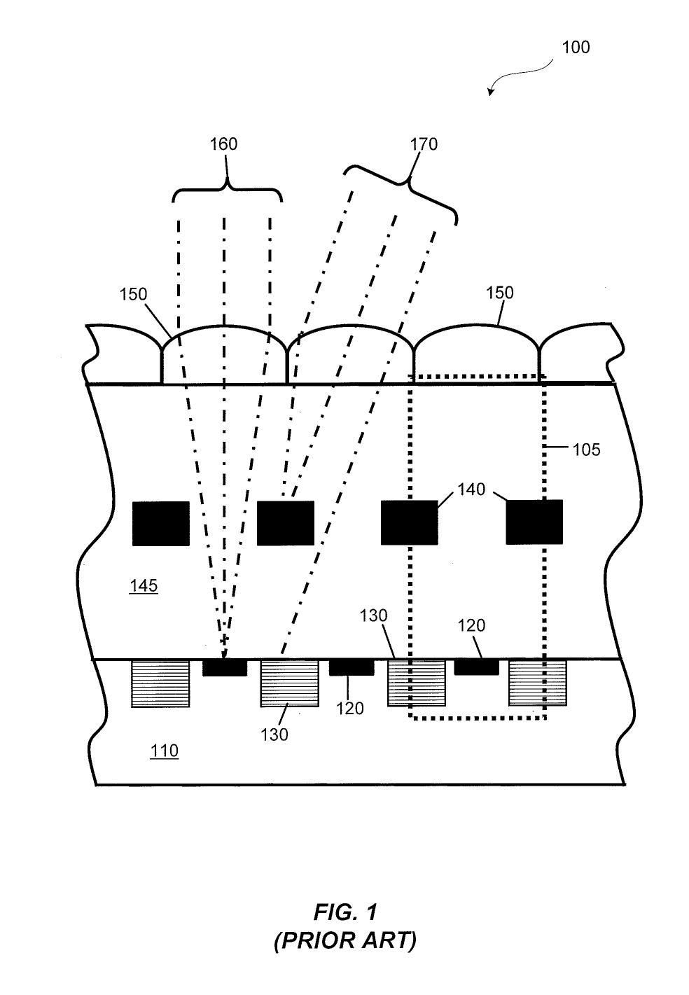

FIG. 2 is a cross-sectional illustration of a portion of a prior art detector pixel array that uses a top-hat design.

FIG. 3 is a cross-sectional illustration of a resonant structure including a photosensitive region, in accordance with an embodiment.

FIG. 4 is a flowchart illustrating a process for designing a resonant structure including a photosensitive region, in accordance with an embodiment.

FIG. 5 is a plot of simulated spectral properties of a red selective resonant structure including a photosensitive region, in accordance with an embodiment.

FIG. 6 is a plot of simulated spectral properties of a green selective resonant structure including a photosensitive region, in accordance with an embodiment.

FIG. 7 is a plot of simulated spectral properties of a blue selective resonant structure including a photosensitive region, in accordance with an embodiment.

FIGS. 8-10 are a set of cross-sectional illustrations of a photosensitive region, each in accordance with an embodiment, shown here to illustrate further exemplary details of the photosensitive region.

FIGS. 11-14 are a set of cross-sectional illustrations of other resonant structures, each in accordance with an embodiment.

FIG. 15 is a cross-sectional illustration of a portion of a detector pixel array incorporating resonant structures, each resonant structure including a photosensitive region, in accordance with an embodiment.

FIG. 16 is another cross-sectional illustration of a portion of a detector pixel array incorporating other exemplary resonant structures, each resonant structure including a photosensitive region, in accordance with an embodiment.

FIG. 17 is a cross-sectional illustration of a compound resonant structure including a plurality of photosensitive regions, in accordance with an embodiment.

FIG. 18 is cross-sectional illustration of a portion of a detector pixel array incorporating compound resonant structures including a plurality of photosensitive regions, in accordance with an embodiment.

FIG. 19 is cross-sectional illustration of a portion of a filtered detector pixel array incorporating a common broadband resonant structure including a plurality of photosensitive regions, in accordance with an embodiment.

FIG. 20 is a plot of simulated spectral properties of a broadband resonant structure including a photosensitive region, in accordance with an embodiment.

FIG. 21 is a flowchart illustrating a process for electromagnetic energy detection using a resonant structure including a photosensitive region, in accordance with an embodiment.

### DETAILED DESCRIPTION OF THE DRAWINGS

Various modifications to the described embodiments may be readily apparent to those skilled in the art upon reading and fully appreciating the disclosure, and the principles herein may be applied to other embodiments. Thus, the present disclosure is not intended to be limited to the embodiments shown but is to be accorded the widest scope consistent with the principles and features described herein. For example, although some examples in the present disclosure may denote the detection of the optical portion of the electromagnetic spectrum, the embodiments disclosed herein are not intended to be limited to this portion of the electromagnetic spectrum but may be adapted for detection of electromagnetic energy outside of optical wavelengths with the use of appropriate materials and thicknesses.

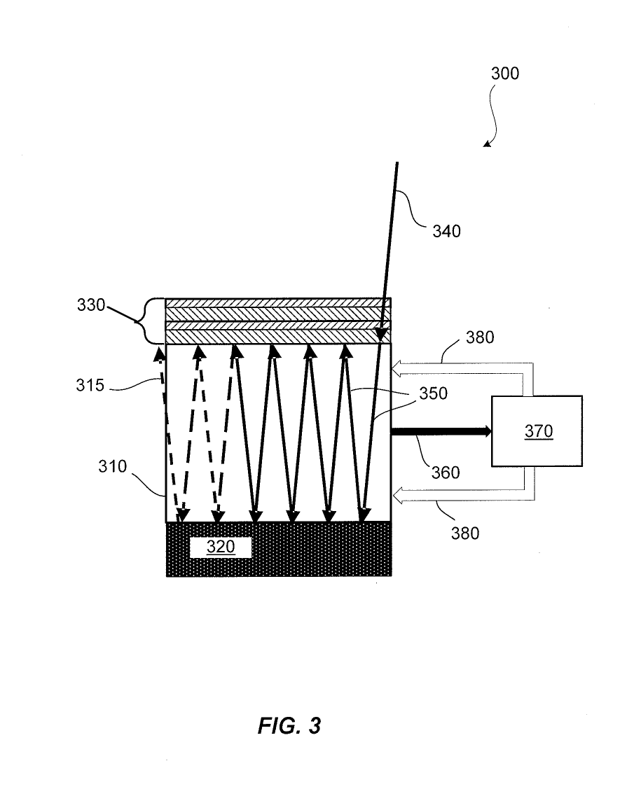

FIG. 3 shows resonant structure 300. Resonant structure 300 includes photosensitive region 310, which is located between two reflective regions (i.e., a reflective layer 320 and a partially reflective layer group 330). Photosensitive region 310, reflective layer 320 and partially reflective layer group 330 may be formed, for example, of stacks of thin film layers. Photosensitive region 310 may be made very thin (e.g., less than 100 nm) so as to reduce the number of defects within photosensitive region 310. Each of reflective layer 320 and partially reflective layer group 330 may be either partially or fully reflective over wavelengths of interest. At least a portion of incident electromagnetic energy 340 is transmitted through partially reflective layer group 330 as resonant electromagnetic energy 350. Resonant electromagnetic energy 350 is resonantly reflected within resonant structure 300 to be detectable by photosensitive region 310. While it is recognized that the reflection of resonant electromagnetic energy 350 within resonant structure 300 may not take place at a specific surface in partially reflective layer group 330, the reflection of resonant electromagnetic energy 350 is shown to occur at the bottom surface of partially reflective layer group 330 for simplicity. Furthermore, it is noted that various components of resonant structure 300, and particularly photosensitive region 310, are not drawn to scale for purposes of clarity.

Upon each reflection of resonant electromagnetic energy 350 from reflective layer 320, a portion of resonant electromagnetic energy 350 may be lost to, for example, absorption by reflective layer 320. Additionally, each time resonant electromagnetic energy 350 transmits through photosensitive region 310, a portion of resonant electromagnetic energy 350 is absorbed thereby such that resonant electromagnetic energy 350 is reduced in magnitude and may be completely absorbed after repeated reflections (as indicated by dashed arrows). In certain applications, reflective layer 320 may be made fully reflective to the wavelengths of interest so as to increase the efficiency of this design by fully reflecting resonant electromagnetic energy 350 back through photosensitive region 310 for detection. Each time that resonant electromagnetic energy 350 traverses photosensitive region 310, a photon may be absorbed. Absorption of a photon may result in generation of an electron-hole pair. The electron and hole may be separated and extracted to generate an electrical output 360 that may be measured by an external circuit 370. Electrical output 360 may be a signal such as a current or a voltage. External circuit 370 may also provide one or more electrical inputs 380 into resonant structure 300.

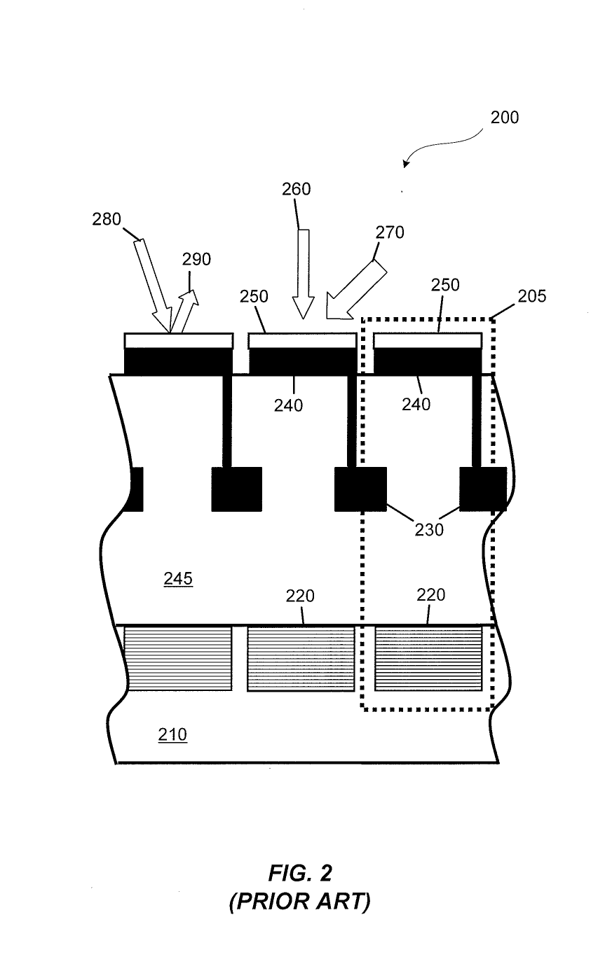

The individual layers of partially reflective layer group 330 may be formed of a variety of materials including, but not limited to, dielectric materials, thin metal layers, or other combinations of materials and thickness. The design of these layers and groups of layers may be facilitated by using commercially available thin film design software. An amount of absorption with each transmission, and a number of reflections required for full absorption, depend upon the specific design of resonant structure 300 including, but not limited to, thickness and material properties of photosensitive region 310, reflective layer 320 and partially reflective layer group 330, and wavelength(s) of incident electromagnetic energy 340. For example, resonant structure 300 may be configured to minimize electromagnetic energy (e.g., within a resonant wavelength band) that exits structure 300 once it has entered therein. In the context of the present disclosure, a resonant wavelength band may be understood to be a wavelength or range of wavelengths for which electromagnetic energy is resonant within a resonant structure (e.g., resonant structure 300). Since substantially all resonant electromagnetic energy 350 may be absorbed within a photosensitive region (i.e., in contrast to reflected electromagnetic energy 290 shown in FIG. 2), resonant structure 300 exhibits greater detection efficiency than a detector system without a resonant structure.

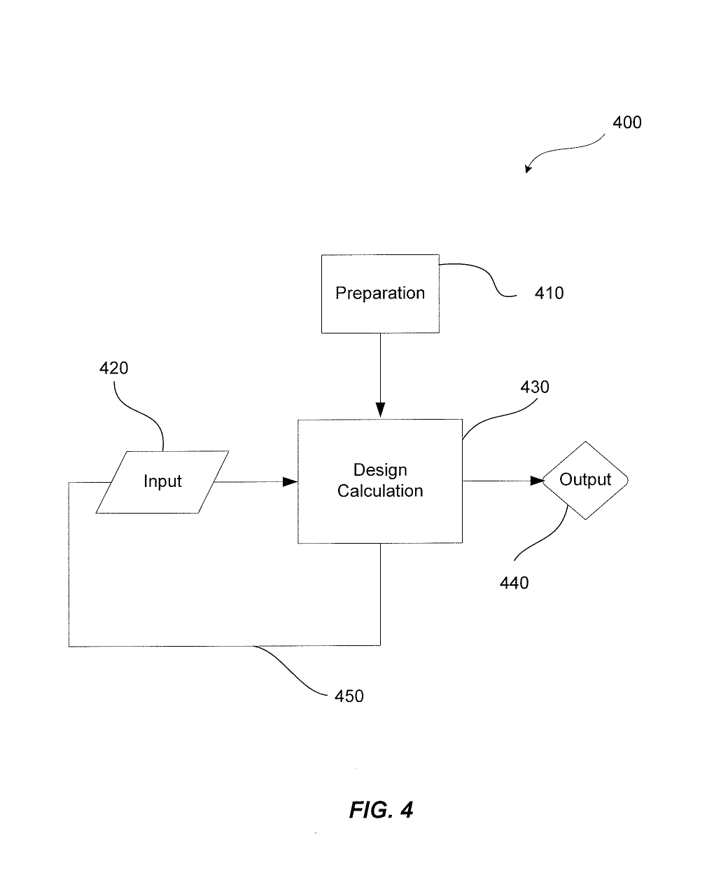

An exemplary process 400 for designing a resonant structure, such as resonant structure 300 of FIG. 3, is shown in FIG. 4. Process 400 begins with a preparation step 410, in which a design process is initiated. For example, an optical design software, such as ESSENTIAL MACLEOD® may be initiated in preparation step 410. Various design parameters are specified in an input 420. The design parameters in input 420 may include, for example, a total number of layers in the resonant structure (such as the photosensitive region, reflective layer and the partially reflective layer group), materials forming those layers (and their material properties such as refractive indices), whether the thickness of certain layers should be fixed or allowed to vary during the design calculations, and one or more wavelengths at which the design calculations are to be performed.

Continuing to refer to FIG. 4, the next step in process 400 is step 430 in which the design calculations are performed. For example, the design calculations may involve the application of electromagnetic energy propagation equations for calculating, for example, the absorptance and reflectance of incident electromagnetic energy through the different layers and at the interfaces defined therebetween. Such calculations may be performed using commercially available thin film design software. By selection of appropriate materials, the effective absorptance and reflectance of the entire resonant structure may be optimized for a variety of applications such as, for instance, the formation of a resonant structure tuned to accept and resonantly reflect at a given wavelength band while transmitting or reflecting other wavelengths. In the context of the embodiment shown in FIG. 3, by designing a resonant wavelength band of resonant structure 300 to fall within a wavelength range detectable by photosensitive region 310, much of resonant electromagnetic energy 350 having wavelengths within the resonant wavelength band may be detected by photosensitive region 310.

Still referring to FIG. 4, step 430 produces an output 440, which includes specification of various parameters of the resonant structure. Output 440 may include, for example, characteristics, such as layer thickness and material, of each layer forming the resonant structure as well as the effective absorptance and reflection from the resonant structure. Process 400 may be returned to step 430, along a path 450, with different input 420 until a desired output 440 is achieved.

TABLE 1

| | | | | Physical |
|---|---|---|---|---|
| | | Refractive | Extinction | Thickness |
| Layer | Material | Index | Coefficient | (nm) |
| Medium | Air | 1.00000 | 0.00000 | |
| 1 | SiO₂ | 1.46180 | 0.00000 | 382.50 |
| 2 | Ta₂O₅ | 2.14455 | 0.00000 | 52.25 |
| 3 | SiO₂ | 1.46180 | 0.00000 | 81.50 |
| 4 | Ta₂O₅ | 2.14455 | 0.00000 | 56.29 |
| 5 | SiO₂ | 1.46180 | 0.00000 | 92.30 |
| 6 | Ta₂O₅ | 2.14455 | 0.00000 | 65.21 |
| 7 | SiO₂ | 1.46180 | 0.00000 | 79.32 |
| 8 | Ta₂O₅ | 2.14455 | 0.00000 | 51.22 |
| 9 | SiO₂ | 1.46180 | 0.00000 | 80.57 |
| 10 | Tₐ2O₅ | 2.14455 | 0.00000 | 54.18 |
| 11 | SiO₂ | 1.46180 | 0.00000 | 76.91 |
| 12 | ITO | 2.05800 | 0.01560 | 10.00 |
| 13 | Si (FILM) | 4.32000 | 0.71800 | 25.00 |
| Substrate | Al | 0.70000 | 5.66333 | |
| | | | | 1107.25 |

TABLE 1 shows an exemplary set of calculated layer design information (e.g., output 440 of FIG. 4) for a red-selective resonant structure based on resonant structure 300 of FIG. 3. TABLE 1 includes the layer number, layer material, material refractive index, material extinction coefficient and layer physical thickness. In the example shown in TABLE 1, “Medium” indicates the material from which electromagnetic energy is incident on the resonant structure. In particular, layers 1-12 correspond to partially reflective layer group 330, layer 13 (“Si (FILM)”) corresponds to photosensitive region 310 and “Substrate” corresponds to reflective layer 320. An indium-tin oxide (ITO) layer 12 is used along with an aluminum “Substrate” layer to provide electrical contact to photosensitive region layer 13, such as for one of inputs 380 or output 360.

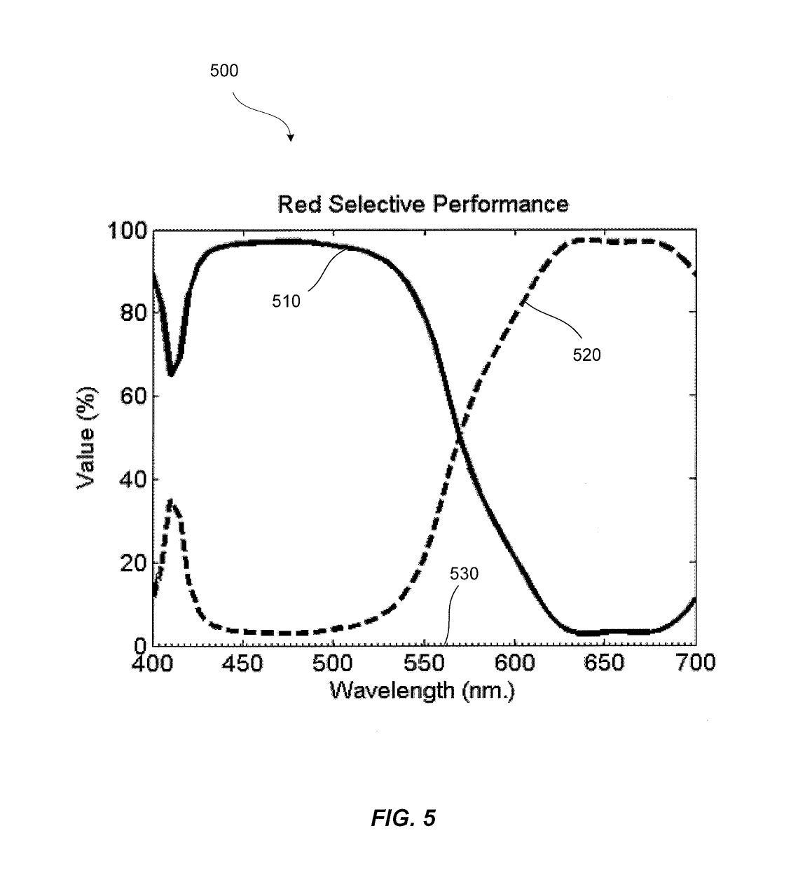

FIG. 5 shows a plot 500 of simulated spectral performance (e.g., output 440 of FIG. 4) of the red selective resonant structure determined with the parameters shown in TABLE 1. Plot 500 has wavelength in nanometers as the abscissa and percentage value of the plotted parameters on the ordinate. A solid line 510 represents the reflectance of the resonant structure as a whole; that is, solid line 510 represents the reflectance as seen by electromagnetic energy (e.g., electromagnetic energy 340) entering the red selective resonant structure from the Medium layer of TABLE 1. A dashed line 520 represents the absorptance of the silicon layer (i.e., layer 13 of TABLE 1) forming the photosensitive region (e.g., photosensitive region 310) within the resonant structure (e.g., resonant structure 300). A dotted line 530, which is nearly coincident with the abscissa, represents the absorptance of layers 1-12 within the resonant structure. The spectral dependence of the absorptance indicates that the photosensitive region within the red-selective resonant structure absorbs nearly 95% of the incident electromagnetic energy in the center of the red wavelengths and less than 10% at blue wavelengths; therefore, the resulting resonant structure is strongly selective toward wavelengths of red electromagnetic energy in the wavelength range from approximately 600 to 700 nanometers.

TABLE 2

| | | | | Physical |
|---|---|---|---|---|
| | | Refractive | Extinction | Thickness |
| Layer | Material | Index | Coefficient | (nm) |
| Medium | Air | 1.00000 | 0.00000 | |
| 1 | Ta₂O₅ | 2.14091 | 0.00000 | 129.56 |
| 2 | SiO₂ | 1.45992 | 0.00000 | 86.13 |
| 3 | Ta₂O₅ | 2.14091 | 0.00000 | 55.34 |
| 4 | SiO₂ | 1.45992 | 0.00000 | 358.33 |
| 5 | ITO | 2.05000 | 0.01400 | 10.00 |
| 6 | Si (FILM) | 4.40000 | 0.63000 | 80.00 |
| 7 | Al | 0.83375 | 6.03250 | 200.00 |
| Substrate | Glass | 1.51852 | 0.00000 | |
| | | | | 919.37 |

TABLE 2 shows an exemplary set of calculated layer design information (e.g., output 440 of FIG. 4) for a green-selective resonant structure based on the resonant structure configuration (i.e., resonant structure 300) illustrated in FIG. 3. In the example shown in TABLE 2, layers 1-5 correspond to partially reflective layer group 330, layer 6 corresponds to photosensitive region 310, and layer 7 corresponds to reflective layer 320.

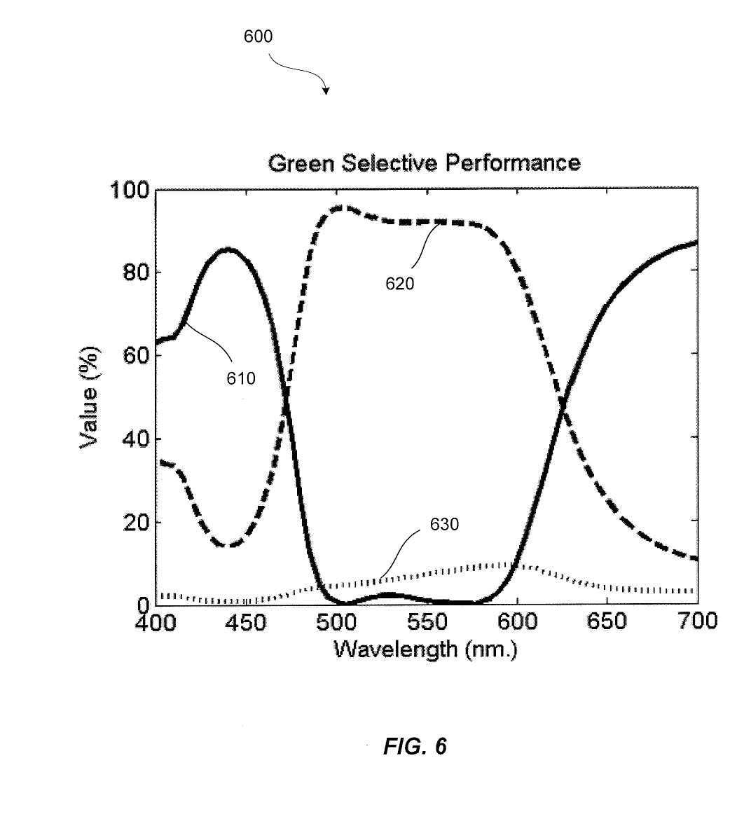

FIG. 6 shows a plot 600 of simulated spectral performance (e.g., output 440 of FIG. 4) of the green selective resonant structure determined with parameters shown in TABLE 2. Like FIG. 5, a solid line 610 represents the reflectance of the resonant structure as a whole. A dashed line 620 represents the absorptance of the silicon layer (i.e., layer 6) forming the photosensitive region within the resonant structure. A dotted line 630 represents the absorptance of layers 1-5 within the green selective resonant structure. It may be seen that the photosensitive region within the green-selective resonant structure absorbs nearly 95% in the center of the green wavelengths and less than 20% at blue and red wavelengths; therefore, the resulting resonant structure is strongly selective toward wavelengths of green electromagnetic energy in the wavelength range from approximately 500 to 600 nanometers.

TABLE 3

| | | | | Physical |
|---|---|---|---|---|
| | | Refractive | Extinction | Thickness |
| Layer | Material | Index | Coefficient | (nm) |
| Medium | Air | 1.00000 | 0.00000 | |
| 1 | Ta₂O₅ | 2.14091 | 0.00000 | 87.83 |
| 2 | SiO₂ | 1.45992 | 0.00000 | 94.36 |
| 3 | Ta₂O₅ | 2.14091 | 0.00000 | 66.72 |
| 4 | SiO₂ | 1.45992 | 0.00000 | 106.66 |
| 5 | Ta₂O₅ | 2.14091 | 0.00000 | 70.87 |
| 6 | SiO₂ | 1.45992 | 0.00000 | 95.97 |
| 7 | Ta₂O₅ | 2.14091 | 0.00000 | 63.59 |
| 8 | SiO₂ | 1.45992 | 0.00000 | 98.17 |
| 9 | Ta₂O₅ | 2.14091 | 0.00000 | 19.72 |
| 10 | ITO | 2.05000 | 0.01400 | 10.00 |
| 11 | Si (FILM) | 4.40000 | 0.63000 | 80.00 |
| 12 | ITO | 2.05000 | 0.01400 | 10.00 |
| 13 | Al | 0.83375 | 6.03250 | 200.00 |
| Substrate | Glass | 1.51852 | 0.00000 | |
| | | | | 1003.87 |

TABLE 3 shows an exemplary set of calculated layer design information (e.g., output 440 of FIG. 4) for a blue-selective resonant structure based on the resonant structure configuration illustrated in FIG. 3. In the example shown in TABLE 3, layers 1-10 correspond to partially reflective layer group 330, layer 11 corresponds to photosensitive region 310, and layers 12-13 correspond to reflective layer 320.

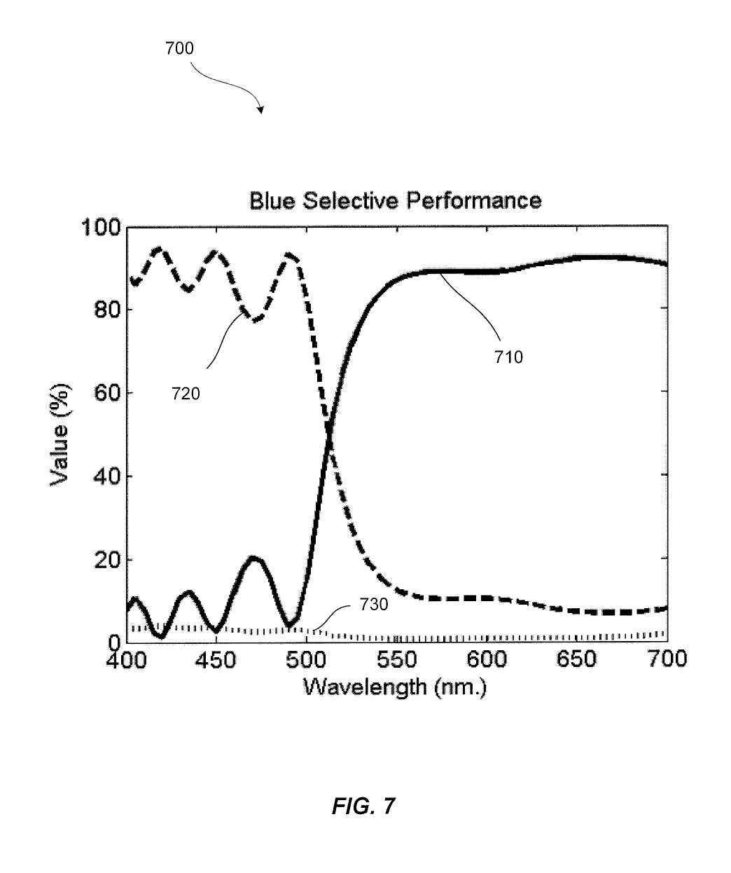

FIG. 7 shows a plot 700 of simulated spectral performance (e.g., output 440 of FIG. 4) of the blue selective resonant structure determined with parameters shown in TABLE 3. In FIG. 7, a solid line 710 represents the reflectance of the resonant structure as a whole, a dashed line 720 represents the absorptance of the silicon layer (i.e., layer 11 of TABLE 3) forming the photosensitive region within the resonant structure, and a dotted line 730 represents the absorptance of layers 1-10 of the blue-selective resonant structure). The spectral response of the absorptance shows that the photosensitive region within the blue-selective resonant structure absorbs nearly 90% in the center of the blue wavelengths and less than 10% at red wavelengths; therefore, the resulting resonant structure is strongly selective toward blue electromagnetic energy in the wavelength range from approximately 400 to 500 nanometers.

TABLE 4

| Material | Wavelength range (nm) |
|---|---|
| Silicon | 190-1100 |
| Germanium | 800-1700 |
| Indium gallium arsenide | 800-2600 |
| Lead sulfide | <1000-3500 |
| Gallium Arsenide | <800 <1500 |
| Lead Selenide | 1000-5000 |
| Mercury Cadmium Telluride | 1000-10000 |

TABLE 4 shows semiconductor materials and the corresponding wavelength bands that may be supported by certain semiconductor materials. For example, silicon is sensitive to wavelengths near 650 nm and, therefore, may be suitable for use within a resonant structure that has a resonant wavelength band from 600 to 700 nm.

Various modifications of resonant structure 300 are possible. For example, by altering the thickness of photosensitive region 310, wavelength(s) that resonate with resonant structure 300 (i.e., those mostly absorbed by photosensitive region 310) may be modified. Also, by modifying the reflective characteristics of reflective layer 320 and/or partially reflective layer group 330, the shape, width and center of the resonant wavelength band may be customized; this tailoring of the resonant wavelength band directly translates to tailoring of the wavelength band absorbed by the photosensitive region. Customization may include, for example, changing thicknesses, material composition, and/or number of layers that are included in partially reflective layer group 330. Due to the complicated interactions of electromagnetic energy and individual thin film layers within a thin film layer stack reflector, it should be understood that altering any layer or a plurality of layers may change the detection, absorption, transmission and reflection properties of the resonant structure.

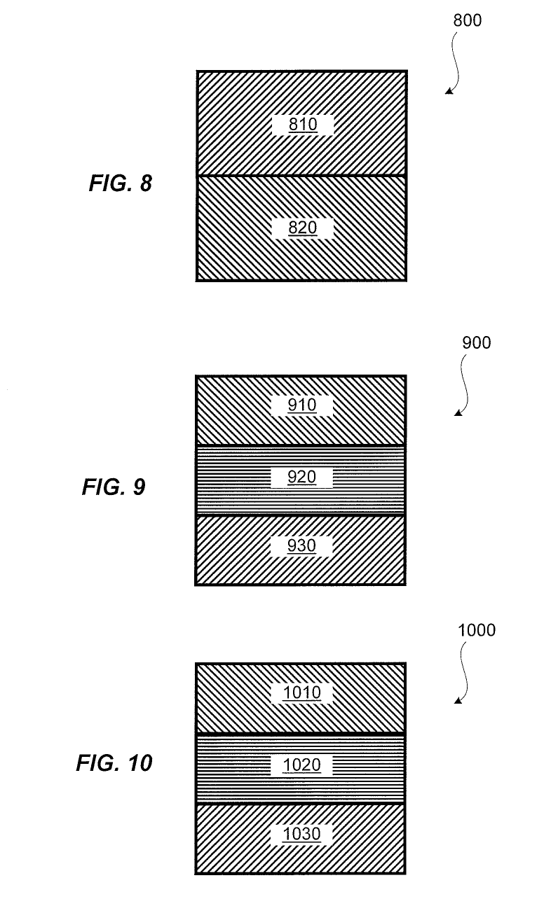

FIGS. 8-10 show cross-sectional views of photosensitive regions 800, 900 and 1000, respectively, suitable for use in resonant structures (including resonant structure 300, FIG. 3). Each of FIGS. 8-10 includes further details of the respective photosensitive region. Photosensitive region 800 includes two subregions 810 and 820, which may be, for example, thin films of either N-type or P-type semiconductors. A photosensitive region thus formed from two subregions of N-type and P-type semiconductors is often termed a thin film photodiode (TFPD). In FIG. 9, photosensitive region 900 includes three subregions 910, 920 and 930. For example, subregions 910, 920 and 930 may be formed from thin films of N-type, intrinsic and P-type semiconductors, respectively. Alternatively, subregions 910, 920 and 930 may be formed of thin films of P-type, intrinsic and N-type semiconductors, respectively. A photosensitive region thus formed from three subregions of N-type, P-type and intrinsic semiconductors is commonly termed a p-i-n photodiode. In FIG. 10, photosensitive region 1000 includes three subregions 1010, 1020 and 1030. For example, subregions 1010, 1020 and 1030 may be formed from thin films of N-type, P-type and N-type semiconductors, respectively. Alternatively, subregions 1010, 1020 and 1030 maybe formed from thin films of P-type, N-type and P-type semiconductors, respectively. Such structures are often referred to as NPN and PNP transistors, respectively.

Continuing to refer to FIGS. 8-10, subregions 810, 820, 910, 920, 930, 1010, 1020 and 1030 may be formed by, for example, depositions of different materials or doping of a common material such as silicon. P-i-n photodiodes may be used as detectors in, for example, full color display (“FCD”) structures (described in more detail below). A NPN or PNP transistor may, for example, provide amplification of a secondary electrical signal. Photosensitive regions including a phototransistor or photodiode may require various electrical inputs (e.g., electrical inputs 380 of FIG. 3) and outputs (e.g., electrical output 360 of FIG. 3).

Another consideration for resonant structures as described above, in connection with FIGS. 8-10, is beam walk-off (“BWO”). BWO, as used herein, denotes a process where electromagnetic energy moves away from or out of a photosensitive region in a stepwise fashion through successive reflections, each reflection impinging on a different location of the reflective surfaces. BWO may exist, for example, when incident electromagnetic energy enters a resonant structure at a non-zero angle of incidence. Left uncontrolled, BWO may result in crosstalk between resonant structures or photosensitive regions when used in detector arrays. For example, with reference to FIG. 3, resonant structure 300 includes reflective layer 320 and partially reflective layer group 330 that are parallel to each other such that resonant structure 300 may be called a parallel planar structure. BWO would occur when resonant electromagnetic energy 350 is not completely absorbed by photosensitive region 310, but is reflected out of resonant structure 300 (e.g., exits from a photosensitive region 310 as indicated by a dashed arrow 315). Due to specular reflection, a parallel planar structure may require additional measures in order to limit BWO, as now described.

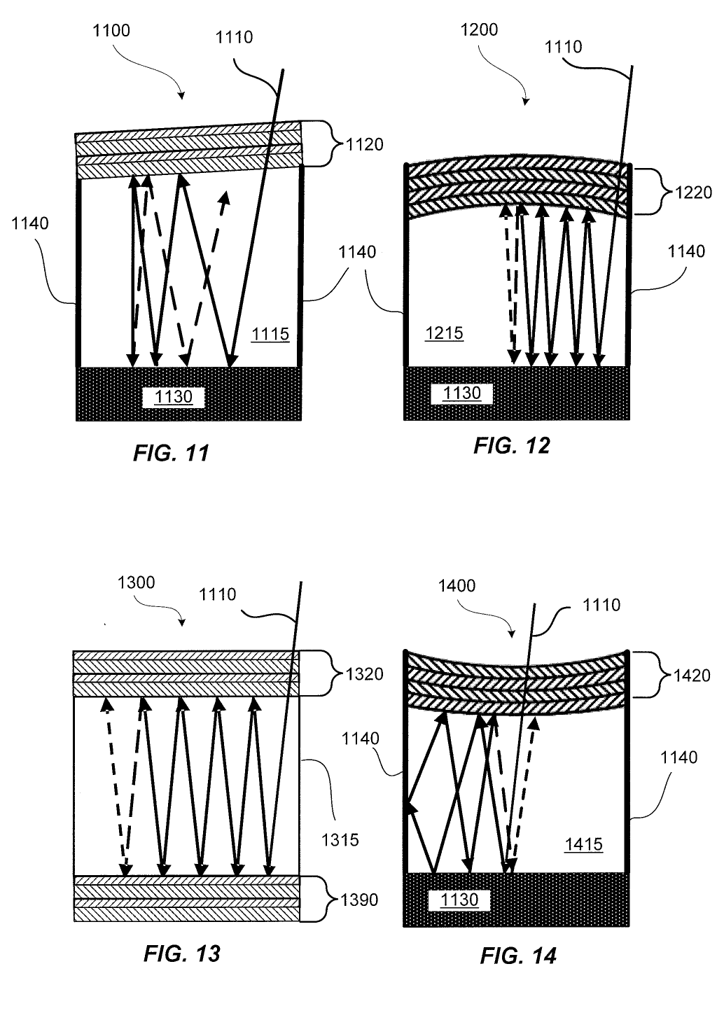

FIGS. 11-14 show a set of cross-sectional illustrations of alternative resonant structures 1100, 1200, 1300 and 1400, respectively, each of which may be used for limiting BWO. Resonant structures 1100, 1200, 1300 and 1400 show additional details and customization that may be included with resonant structure 300 of FIG. 3. Each of resonant structures 1100, 1200, 1300 and 1400 includes a photosensitive region “sandwiched” between two reflective regions that multiply reflect incoming electromagnetic energy through the photosensitive region.

Particularly referring to FIG. 11, resonant structure 1100 includes a photosensitive region 1115 with a tilted partially reflective layer group 1120 and a reflective layer 1130. Tilted partially reflective layer group 1120 may be formed from, for example, a stack of thin films, while reflective layer 1130 may be formed from, for instance, a single layer of material such as a metal (e.g., aluminum or copper). Non-planar 2D or 3D tilt of tilted partially reflective layer group 1120 may be used for limiting BWO and crosstalk in a detector array. That is, the tilt of tilted partially reflective layer group 1120 allows capture of more electromagnetic energy 1110 with a higher incidence angle than would be allowed by a non-tilted partially reflective layer group, such as partially reflective layer group 330 shown in FIG. 3, because electromagnetic energy of off-normal incidence may be reflected within resonant structure 1100 a larger number of times without BWO in comparison to in a parallel planar structure. That is, the tilt of partially reflected layer group 1120 helps to limit BWO by directing successive reflections away from one or more edges of photosensitive region 1115.

Still referring to FIG. 11, resonant structure 1100 may include additional elements such as barriers 1140 at the edges of resonant structure 1100 for limiting an amount of electromagnetic energy exiting from the edges once it has entered photosensitive region 1115. Barriers 1140 may be formed of, for instance, dielectric or metallic materials. For example, layered materials of high index differences may be used to create reflecting surfaces as barriers 1140. Barriers 1140 may further limit BWO by blocking stray light that is directed out of the edges of the photosensitive regions. In one example, barriers 1140 may be configured to be reflective so as to reflect light incident thereon back into the resonant structure.

In FIG. 12, resonant structure 1200 includes a photosensitive region 1215 and a convex partially reflective layer group 1220. The curved shape of convex partially reflective layer group 1220 also helps to keep electromagnetic energy 1110 contained within resonant structure 1200, as indicated by arrows within photosensitive region 1215. That is, curvature of convex partially reflective layer group 1220 helps to limit BWO by directing successive reflections away from one or more edges of photosensitive region 1215. In other words, convex partially reflective layer group 1220 directs successive reflections of electromagnetic energy 1110 towards a center of resonant structure 1200 and photosensitive region 1215.

Turning to FIG. 13, resonant structure 1300 does not include barriers 1140 but incorporates a photosensitive region 1315 between a first reflective layer group 1320 and a second reflective layer group 1390, which replaces reflective layer 1130 of FIGS. 11 and 12 and is formed from multiple thin film layers. The use of two reflective layer groups provides additional customizability in the absorption and reflection characteristics of resonant structure 1300 such that electromagnetic energy 1110 may be more efficiently contained within and absorbed by photosensitive region 1315.

In FIG. 14, resonant structure 1400 includes a photosensitive region 1415 and a concave partially reflective layer group 1420. In resonant structure 1400, concave partially reflective layer group 1420, in combination with reflective barriers 1140, may serve to distribute electromagnetic energy 1110 throughout photosensitive region 1415 for increased detection efficiency.

Again referring to FIGS. 11-14, a variety of modifications to the embodiments shown in these figures are possible. For instance, although resonant structures 1100, 1200 and 1400 incorporate non-planar, partially reflective layer groups 1120, 1220 and 1420, it should be understood that reflective layer 1130 may be modified instead of or simultaneously with partially reflective layers 1120, 1220 and 1420. That is, for instance, reflective layer 1130 may be tilted or curved while partially reflective layer groups 1120, 1220 and 1420 may be replaced with a planar reflective layer group such as reflective layer group 330 of FIG. 3. Additionally, tilt and/or curvature of partially reflective layer groups (e.g., partially reflective layer groups 1120, 1220, 1320, 1390 and 1420) may be coordinated with an incidence angle of electromagnetic energy 1110 such that substantially all of energy 1110 is absorbed within photosensitive regions 1115, 1215, 1315 and 1415, respectively. Accordingly, a convex or concave reflective layer group (e.g., partially reflective layer groups 1220 and 1420) may act like a lens to direct electromagnetic energy 1110 away from barriers 1140 or, alternatively, cooperate with barriers 1140 to keep electromagnetic energy 1110 within the resonant structure. A planar but non-parallel structure (e.g., structure 1100) may then act like, for instance, a prism to direct resonant electromagnetic energy 1110 within photosensitive region 1115.

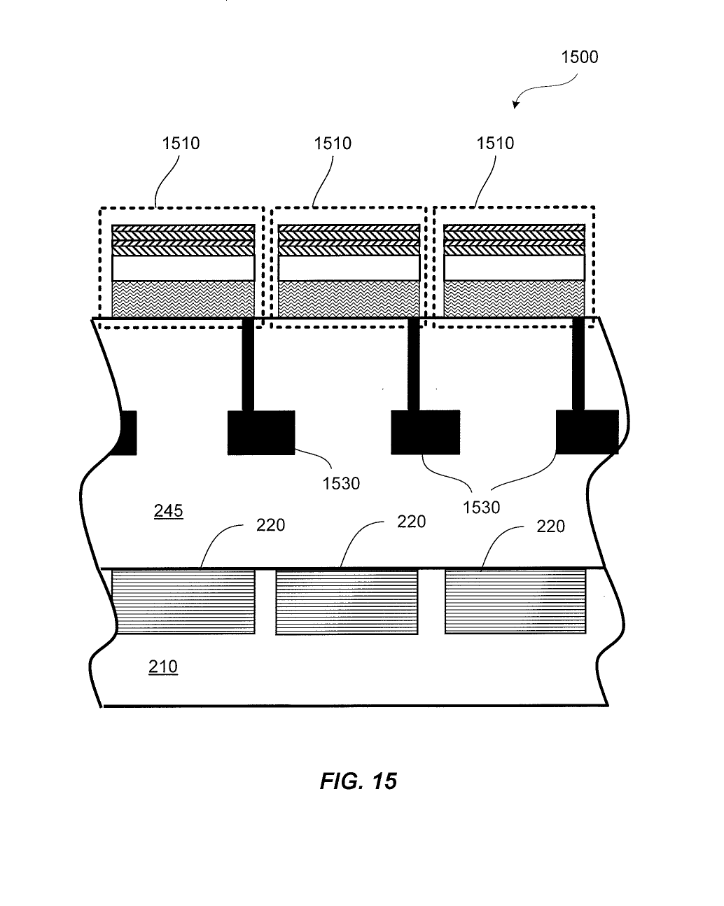

FIG. 15 shows a cross-sectional illustration of a portion of a detector pixel array 1500 incorporating a plurality of resonant structures 1510, shown here to illustrate a configuration in which the resonant structures of the present disclosure are incorporated into a horizontal array, in a manner analogous to prior art detector pixel array 200 of FIG. 2. Each resonant structure 1510 may be, for example, one of resonant structure 300 of FIG. 3 and resonant structures 1100, 1200, 1300 and 1400 of FIGS. 11-14. In detector pixel array 1500, each resonant structure 1510 is directly connected with a conductive trace 1530.

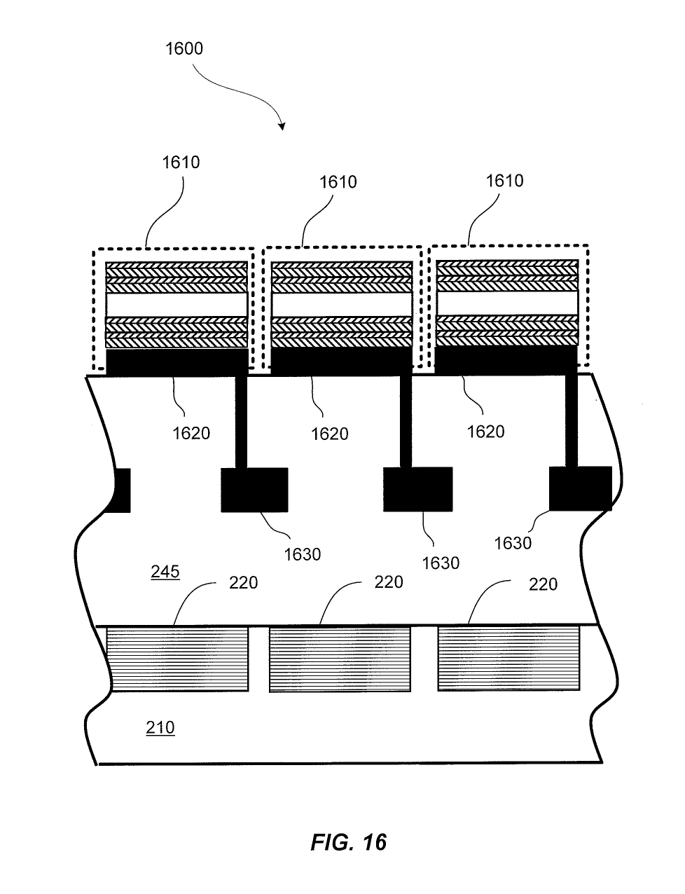

FIG. 16 shows a cross-sectional illustration of a portion of another detector pixel array 1600 incorporating resonant structures 1610, shown here to illustrate another horizontal array configuration. In FIG. 16, each resonant structure 1610 may be, for example, one of resonant structure 300 of FIG. 3 and resonant structures 1100, 1200, 1300 or 1400 of FIGS. 11-14. In contrast to detector pixel array 1500, in which conductive trace 1530 is directly connected with each resonant structure 1510, each resonant structure 1610 in FIG. 16 is disposed on top of a separate, conductive layer 1620, which is in turn connected with a conductive trace 1630. This design provides additional flexibility in the layer design of resonant structure 1610 in comparison to that of resonant structure 1510.

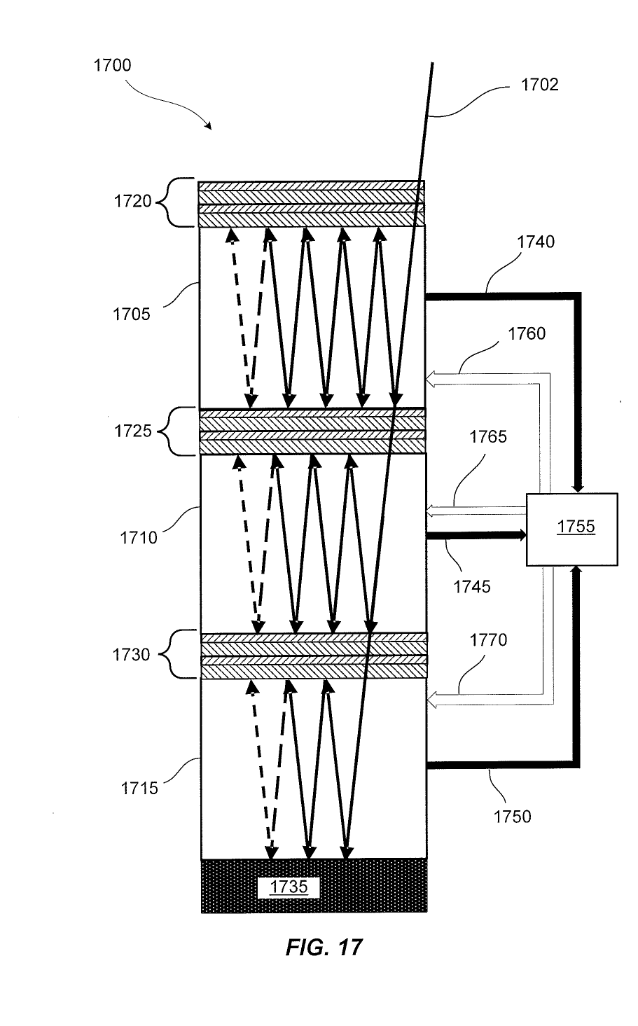

FIG. 17 is a cross-sectional illustration of a compound resonant structure, shown here to illustrate a vertical stack configuration of multiple resonant structures. A compound resonant structure 1700 includes three photosensitive regions 1705, 1710 and 1715 formed between reflective regions (e.g., partially reflective layer groups 1720, 1725 and 1730 and a reflective layer 1735 as shown in FIG. 17). Each partially reflective layer group may be configured to transmit specific wavelengths or ranges of wavelengths of electromagnetic energy 1702 incident thereon so that they may be detected by subsequent photosensitive regions. Compound resonant structure 1700 may be designed such that specific wavelengths or ranges of wavelengths of electromagnetic energy are resonantly collected within each photosensitive region 1705, 1710 and 1715. For example, partially reflective layer groups 1720 and 1725 along with photosensitive layer 1705 may form a resonant structure for detecting blue wavelengths of electromagnetic energy while simultaneously transmitting red and green wavelengths. That is, each portion of compound resonant structure 1700 may be optimized using the procedure outlined in FIG. 4 for operation in a desired wavelength range.

Continuing to refer to FIG. 17, photosensitive regions 1705, 1710 and 1715 may provide electrical outputs 1740, 1745 and 1750 (indicated by dark arrows), respectively, in accordance with electromagnetic energy absorbed therein. Electrical outputs 1740, 1745 and 1750 may be detected and processed, for example, by a processor 1755. Processing of electrical outputs 1740, 1745 and 1750 may allow the derivation of color information such that compound resonant structure 1700 forms a FCD structure. In one exemplary FCD structure, photosensitive region 1705 is optimized in association with partially reflective layer groups 1720 and 1725 for blue wavelength detection, photosensitive region 1710 is optimized in association with partially reflective layer groups 1725 and 1730 for green wavelength detection, and photosensitive region 1715 is optimized in association with partially reflective layer group 1730 and reflective layer 1735 for red wavelength detection. The exemplary FCD structure may then allow discrimination of red-green-blue (“RGB”) color information by separately detecting and processing electrical outputs 1740, 1745 and 1750 at processor 1755. Processor 1755 may additionally provide electrical inputs 1760, 1765 and 1770 (indicated by white arrows) which may be used for controlling photosensitive regions 1705, 1710 and 1715 in, for example, a feedback configuration which adjusts the detection sensitivity of one or more of photosensitive regions 1705, 1710 and 1715 in accordance with electrical outputs 1740, 1745 and 1750 fed into processor 1755. For instance, if electromagnetic energy 1702 contains a large percentage of red wavelengths with a smaller component of green wavelengths, then electronic output 1750 (corresponding to red wavelength detection) is higher than electronic output 1745 (corresponding to green wavelength detection). In order to obtain better sensitivity for green wavelengths, electrical input 1770 may be adjusted to reduce the red wavelength detection while electrical input 1765 may be adjusted to boost green wavelength detection.

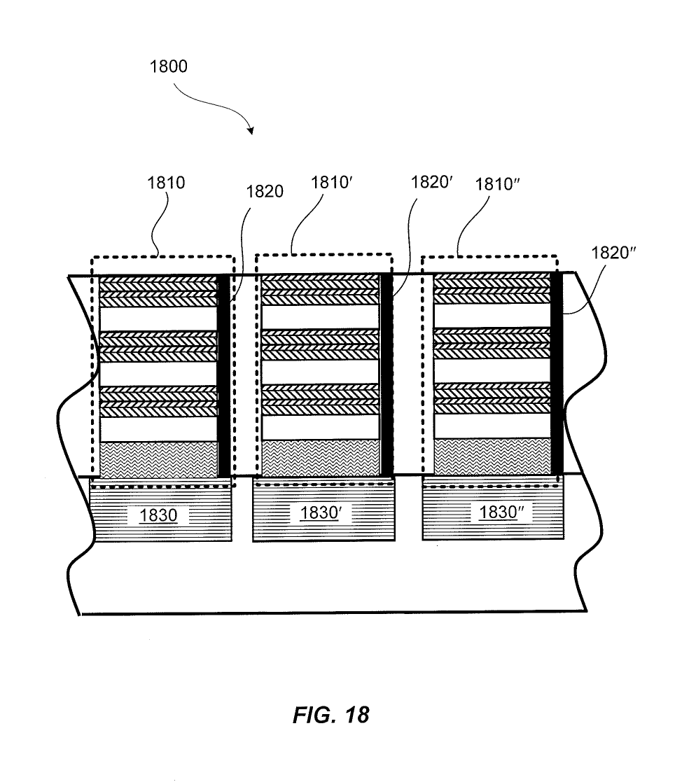

FIG. 18 is a cross-sectional illustration of a portion of a detector pixel array, shown to here to illustrate a horizontal array configuration of multiple compound resonant structures. A detector pixel array 1800 includes a plurality of compound resonant structures 1810, 1810′ and 1810″. Each compound resonant structure may be a FCD structure, such as compound resonant structure 1700 of FIG. 17. Each compound resonant structure 1810, 1810′ and 1810″ may vary in lateral dimension from each other. Conductive traces 1820, 1820′ and 1820″, connected with resonant structures 1810, 1810′ and 1810″, may transfer electrical signals to and from detector pixel read circuits 1830, 1830′ and 1830″, which may detect and at least partially process the electrical signals or provide control signals into resonant structures 1810, 1810′ and 1810″, respectively. At least one of the compound resonant structures may be tuned to detect a different set of wavelengths from others so as to allow polychromatic detection across the horizontal array. For instance, resonant structure 1810 may be tuned for RGB detection (such as was shown in FIG. 17) while resonant structure 1810′ may be tuned for cyan-magenta-yellow (“CMY”) detection.

The number of photosensitive regions in compound resonant structures such as those shown in FIGS. 17 and 18 may be varied. Additionally, the resonant wavelength or band of wavelengths associated with each photosensitive region may be varied. For example, a compound resonant structure with two photosensitive regions that provide resonant detection for separate wavelength bands may be used to form a visible and infrared wavelength detector structure. Specifically referring to the examples shown in FIGS. 17 and 18, the combination of photosensitive regions 1705 and 1710 and partially reflective layer groups 1720, 1725 and 1730 may be optimized (using a process such as that shown in FIG. 4) for detection of electromagnetic energy in a visible wavelength range, while the combination of photosensitive region 1715, partially reflective layer group 1730 and reflective layer 1735 may be configured for detection of electromagnetic energy in an infrared wavelength range. An array of such structures (e.g., in a configuration such as detector pixel array 1800 of FIG. 18) may be used in hyperspectral imaging applications. Moreover, the combination of photosensitive regions 1705 and 1710 and partially reflective layer groups 1720, 1725 and 1730 may be optimized (using a process such as that shown in FIG. 4) for detection of electromagnetic energy over the same wavelength range so as to provide, for instance, grayscale volumetric imaging. Other applications for compound resonant structures may include, but are not limited to, multiple plane image capture and phase sensitive imaging.

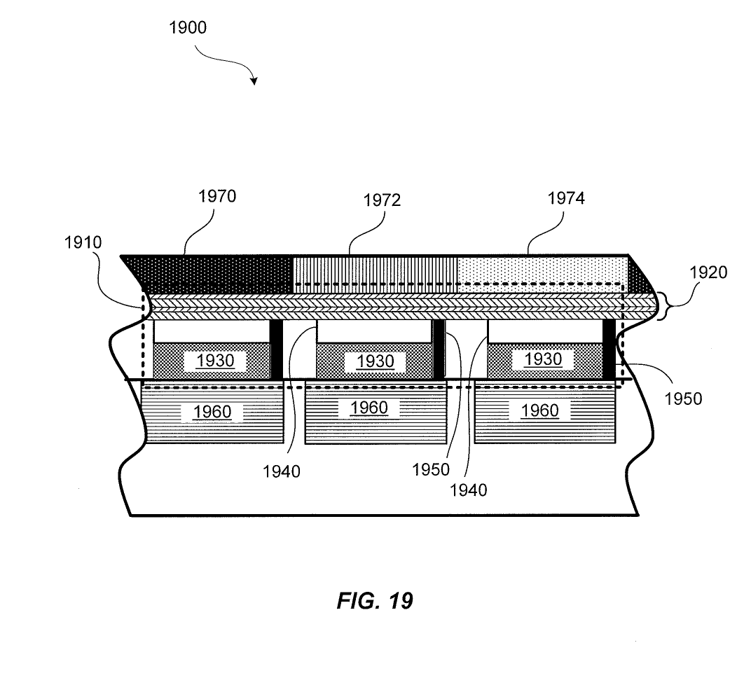

FIG. 19 shows a cross-sectional illustration of a portion of a filtered detector pixel array. Detector pixel array 1900 includes broadband resonant structure 1910. Broadband resonant structure 1910 is defined by a common, reflective layer group 1920 and a plurality of reflective layers 1930 sandwiching a plurality of multiple photosensitive regions 1940. The common partially reflective layer group is disposed across multiple photosensitive regions 1940. Each photosensitive region 1940 and its associated reflective layer 1930 may be physically, optically and/or electrically isolated from other photosensitive regions 1940. The electrical output generated by each photosensitive region 1940 may be transferred by a conductive trace 1950 to a detector pixel read circuit 1960 for processing. As shown in FIG. 19, detector pixel array 1900 further includes filters 1970, 1972 and 1974 that selectively absorb, reflect or transmit different wavelengths of electromagnetic energy. For example, filter 1970 may allow transmission of electromagnetic energy of red wavelengths therethrough, filter 1972 may transmit green wavelengths and filter 1974 may allow transmission of blue wavelengths. In this example, detector pixel array 1900 will function as a color selective RGB detector pixel array by selective filtering. Filters 1970, 1972 and 1974 may be formed from, for example, thin film stacks or from selectively absorptive polymers. Alternatively, in the absence of filters 1970, 1972 and 1974 resulting broadband resonant structure 1910 including common, reflective layer group 1920 formed over a large area amorphous thin film detector may function as a basis of an amorphous solar cell. That is, with the appropriate design for common reflective layer group 1920, reflective layers 1930 and photosensitive regions 1940, the resulting broadband resonant structure is capable of resonantly reflecting and efficiently receiving electromagnetic energy over a range of wavelengths suitable for, for instance, solar cell applications.

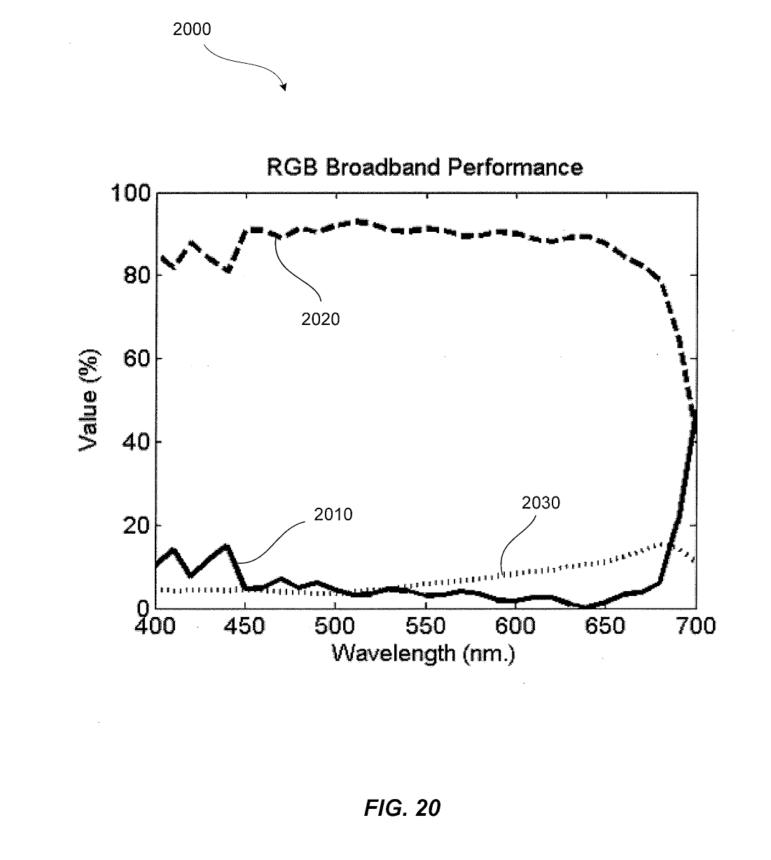

FIG. 20 shows a plot 2000 of the simulated spectral performance of an RGB broadband resonant structure including a photosensitive region. Plot 2000 has wavelength in nanometers as the abscissa and the value in percentage of the plotted parameters on the ordinate. A solid line 2010 represents the percentage value of the reflectance of the compound resonant structure. A dashed line 2020 represents the absorptance of the silicon layer, which forms the photosensitive region within the resonant structure. The spectral dependence of the absorptance 2020 indicates that the photosensitive region within the broadband resonant structure is capable of absorbing more than 80% at most wavelengths from 400 to 700 nm. A dotted line 2030 represents the absorptance of all other layers except for the silicon layer forming the photosensitive region of the broadband resonant structure. The spectral properties of the broadband resonant structure show that the structure is efficient in detecting electromagnetic energy at any wavelength from 400 to 700 nm and therefore filters (such as, for example, filters 1970, 1972 and 1974 of FIG. 19) may be added to form subregions (e.g., individual detector pixel elements) that are wavelength selective.

TABLE 5

| | | Refractive | Extinction | Physical |
|---|---|---|---|---|
| Layer | Material | Index | Coefficient | Thickness (nm) |
| Medium | Air | 1 | 0 | |
| 1 | SiO2 | 1.45344 | 0 | 102.19 |
| 2 | Ta2O5 | 2.11818 | 0 | 29.74 |
| 3 | SiO2 | 1.45344 | 0 | 184.95 |
| 4 | Ta2O5 | 2.11818 | 0 | 235.71 |
| 5 | SiO2 | 1.45344 | 0 | 190.2 |
| 6 | Ta2O5 | 2.11818 | 0 | 19.18 |
| 7 | SiO2 | 1.45344 | 0 | 171.02 |
| 8 | Ta2O5 | 2.11818 | 0 | 101.03 |
| 9 | SiO2 | 1.45344 | 0 | 148.64 |
| 10 | Ta2O5 | 2.11818 | 0 | 242.59 |
| 11 | SiO2 | 1.45344 | 0 | 64.68 |
| 12 | Ta2O5 | 2.11818 | 0 | 45.76 |
| 13 | ITO | 1.914 | 0.01 | 15 |
| 14 | Si (FILM) | 4.06 | 0.21 | 90 |
| Substrate | Al | 1.99 | 7.05 | |
| Total | | | | 1640.69 |
| Thickness | | | | |

TABLE 5 shows the calculated layer design information for the broadband resonant structure corresponding to the spectral performance plot shown in FIG. 20 as calculated, for example, by the process outlined in FIG. 4. In the example shown in TABLE 5, Layers 1-13 correspond to the partially reflective layer group, layer 14 (“Si (FILM)”) corresponds to the photosensitive region, and “Substrate”, in this example formed of aluminum, corresponds to the reflective layer.

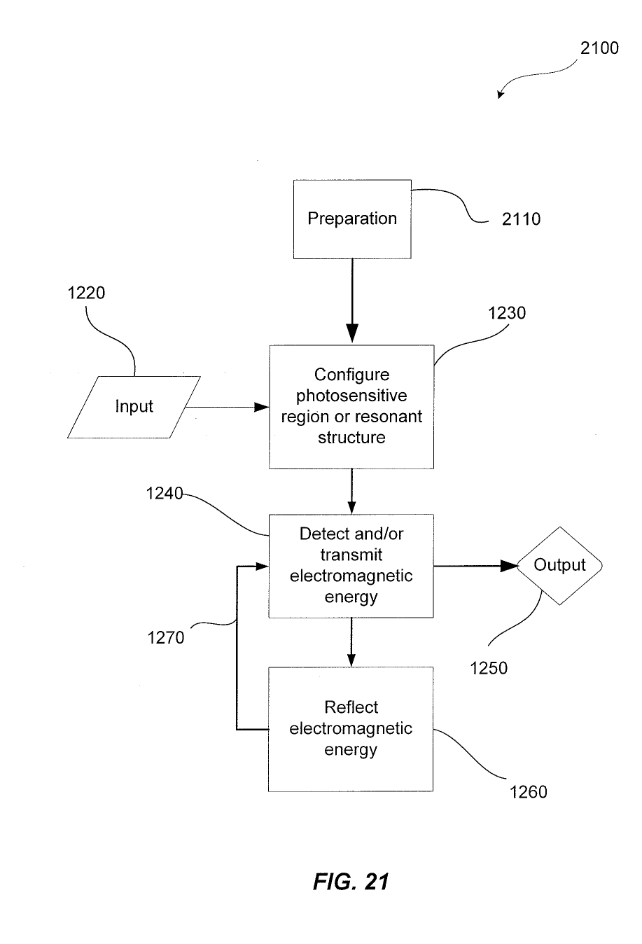

Any of the above described resonant structures including a photosensitive region may be configured and utilized according to process 2100 shown in FIG. 21. Process 2100 begins with a preparation step 2110, in which a photosensitive region, such as photosensitive region 315 of FIG. 3, or resonant structure, such as resonant structure 300 of FIG. 3, is prepared for use. The preparation may include actual fabrication or connection to external systems. One or more inputs 1220 are provided for a configuring step 1230. An input such as the thickness of the photosensitive region is provided prior to fabrication of the resonant structure to configure, for example, the wavelengths of electromagnetic energy that are resonant with the structure. An input, such as inputs 380 of FIG. 3, may be provided during or just prior to utilization of the resonant structure to configure, for example, a sensitivity or gain factor. In step 1240, the electromagnetic energy is detected and/or transmitted depending upon the properties and configuration of the resonant structure or photosensitive region. The portion of the electromagnetic energy that is detected may be used to generate output 1250 as a current of voltage signal. Next, in step 1260, at least a portion of the electromagnetic energy is reflected back into the photosensitive region (as indicated by pathway 1270) for subsequent detection and/or transmission. The steps of detection/transmission and reflection (e.g., 1240 and 1260) may continue until no electromagnetic energy remains.

Although each of the aforedescribed embodiments has been illustrated with various components having particular respective orientations, it should be understood that the embodiments as described in the present disclosure may take on a variety of specific configurations with the various components being located in a variety of positions and mutual orientations and still remain within the spirit and scope of the present disclosure. Furthermore, suitable equivalents may be used in place of or in addition to the various components, the function and use of such substitute or additional components being held to be familiar to those skilled in the art and are therefore regarded as falling within the scope of the present disclosure. Although, in the embodiments described above, silicon is used as a photosensitive material, aluminum is used as a reflective layer and SiO₂ and Ta₂O₅ are used to form partially reflective layer groups, other materials may be employed. For example, a photosensitive material may be formed from indium gallium arsenide, a reflective layer may be formed from copper or silver and a partially reflective layer group may be formed from silicon nitride and silicon dioxide. Therefore, the present examples are to be considered as illustrative and not restrictive, and the disclosure is not to be limited to the details given herein but may be modified within the scope of the appended claims.

What is claimed is:

1. An electromagnetic energy detection system for detecting electromagnetic energy incident thereon, the system comprising a resonant structure having first and second reflective regions separated by a photosensitive region such that electromagnetic energy entering the resonant structure is multiply reflected therein for detection by the photosensitive region.

2. The electromagnetic energy detection system of claim 1, wherein the photosensitive region is at least partially formed from an amorphous material.

3. The electromagnetic energy detection system of claim 2, wherein the amorphous material is less than 100 nm in thickness.

4. The electromagnetic energy detection system of claim 1, wherein the resonant structure is configured for selectively reflecting electromagnetic energy within a wavelength range while electromagnetic energy outside of the wavelength range is removed from the resonant structure by at least one of absorption, reflection and transmission.

5. The electromagnetic energy detection system of claim 1, further comprising an array of resonant structures for use as a detector array.

6. The electromagnetic energy detection system of claim 1, wherein the photosensitive region is at least partially formed from a crystalline material.

7. The electromagnetic energy detection system of claim 1, wherein the photosensitive region forms a thin film photodiode.

8. The electromagnetic energy detection system of claim 1, wherein the photosensitive region forms a thin film phototransistor.

9. The electromagnetic energy detection system of claim 1, wherein the photosensitive region includes sublayers of p-type semiconductor, intrinsic semiconductor and n-type semiconductor materials.

10. The electromagnetic energy detection system of claim 1, wherein the resonant structure includes at least first and second photosensitive regions.

11. The electromagnetic energy detection system of claim 10, wherein the first and second photosensitive regions are configured for detecting a first wavelength range and a different, second wavelength range, respectively.

12. The electromagnetic energy detection system of claim 10, wherein the first and second photosensitive regions are configured for detecting electromagnetic energy over a given wavelength range.

13. The electromagnetic energy detection system of claim 10, wherein the first and second photosensitive regions are stacked vertically.

14. The electromagnetic energy detection system of claim 10, wherein the first photosensitive region detects electromagnetic energy in a first wavelength range while allowing electromagnetic energy outside of the first wavelength range to be transmitted therethrough, wherein the second photosensitive region detects electromagnetic energy in a second wavelength range while allowing electromagnetic energy outside of the second wavelength range to be transmitted therethrough.

15. The electromagnetic energy detection system of claim 14, further comprising a third photosensitive region for detecting electromagnetic energy in a third wavelength range.

16. The electromagnetic energy detection system of claim 15, wherein each of the first, second and third wavelength ranges comprises blue, green and red wavelength ranges, respectively.

17. The electromagnetic energy detection system of claim 1, wherein the resonant structure includes a non-planar surface to alleviate beam walk off.

18. The electromagnetic energy detection system of claim 1, further comprising at least one barrier adjacent to the photosensitive region.

19. A method for electromagnetic energy detection using a photosensitive region, the method comprising:
configuring the photosensitive region such that the photosensitive region detects a portion of the electromagnetic energy incident thereon while transmitting, without detection, a remainder of the electromagnetic energy therethrough; and
reflecting a portion of the remainder of the electromagnetic energy back into the photosensitive region for detection by the photosensitive region.

20. The method of claim 19, further comprising repeating the reflecting such that the portion of the remainder of the electromagnetic energy is multiply reflected into the photosensitive region.

21. The method of claim 20, wherein multiply reflecting comprises selectively reflecting electromagnetic energy within a wavelength range while selectively absorbing electromagnetic energy outside of the wavelength range.

22. The method of claim 21, wherein multiply reflecting comprises selectively reflecting electromagnetic energy within a wavelength range while selectively transmitting electromagnetic energy outside of the wavelength range.

23. The method of claim 19, wherein configuring the photosensitive region comprises reducing the thickness of the photosensitive region to less than 100 nm.

24. Resonant structure for electromagnetic energy detection, comprising:
first and second reflective regions separated by a photosensitive region such that electromagnetic energy entering the resonant structure is multiply reflected therein for detection by the photosensitive region.

25. Resonant structure of claim 24, the first reflective region comprising a partially reflective layer group that transmits a wavelength band of interest, the second reflective region being mostly reflective to the wavelength band of interest, the photosensitive region being 100 nm or less in thickness such that the number of defects available for recombination is reduced.

26. Resonant structure of claim 24, one or both of the first and second reflective regions being curved or tilted to alleviate beam walk off.

27. A detector array, comprising:
an array of resonant structures, each of the resonant structures having first and second reflective regions separated by a photosensitive region such that electromagnetic energy entering the resonant structure is multiply reflected therein for detection by the photosensitive region.

28. The detector array of claim 27, each of the resonant structures being staked with at least one additional photosensitive region separated by a pair of reflective regions sensitive to a different waveband, such that the waveband of electromagnetic energy entering the additional photosensitive region resonant structure is multiply reflected therein for detection by the additional photosensitive region.
